(19) United States
(12) Patent Application Publication
(10) Pub. No.: US 2010/0020513 A1
(43) Pub. Date: Jan. 28, 2010

(54) INTEGRATED MICROWAVE CIRCUIT

(75) Inventors: Graham Lawson, Crawley (GB); Emmanuel Loiselet, Horsham (GB)

Correspondence Address: DARBY & DARBY P.C., P.O. BOX 770, Church Street Station, New York, NY, 10008-0770, US

(73) Assignee: Thales Holdings UK PLC, Surrey (GB)

(21) Appl. No.: 12/499,364

(22) Filed: Jul. 8, 2009

(30) Foreign Application Priority Data
Jul. 15, 2008 (GB) 0812911.6

(51) Int. Cl. H05K 5/00

(52) U.S. Cl. 361/753

(57) ABSTRACT

An hermetically sealed integrated microwave circuit comprising a coplanar waveguide on a printed circuit board (PCB) electrically connected on one major surface to an integrated circuit, and thermally and electrically connected to a ball grid array (BGA) on its opposite major surface, in which the PCB has at least first and second printed layers, a microwave signal path extends from a ball of the BGA through a through-hole in both printed layers to the coplanar wave guide, and plural ground paths extend from balls of the BGA through first through-holes in the first printed layer of the PCB and through second through-holes of the second printed layer of the PCB, the first and second through-holes being non-coincident, to allow for an hermetic seal across the PCB whilst introducing a predetermined impedance in the PCB between the signal and ground paths.

### FIELD OF THE INVENTION

This invention relates to an hermetically sealed integrated microwave circuit comprising a waveguide on a PCB, printed circuit board, electrically connected on one major surface to an IC, integrated circuit, and thermally and electrically connected to a BGA, ball grid array, on its opposite major surface.

### BACKGROUND OF THE INVENTION

Difficulties with such integrated circuit structures for microwave signals arise in the RF transition between layers. The purpose of the present invention is to drive a radio frequency, RF, signal from internal layers of a PCB motherboard to a micro BGA component mounted on the upper face of the motherboard, with good RF performance, and satisfactory insertion losses and return losses. It has been difficult to provide a satisfactory RF transition whilst maintaining hermetic seals for the package, and good reliability in use, particularly with thermal stress and vibration.

Accordingly, the present invention provides an hermetically sealed integrated microwave circuit comprising a coplanar waveguide on a PCB electrically connected on one major surface to an IC, and thermally and electrically connected to a BGA on its opposite major surface, in which the PCB has at least first and second printed layers, a microwave signal path extends from a ball of the BGA through a through-hole in both printed layers to the coplanar waveguide, and plural ground paths extend from balls of the BGA through first through-holes in the first printed layer of the PCB and through second through-holes of the second printed layer of the PCB, the first and second through-holes being non-coincident, to allow for an hermetic seal across the PCB whilst introducing a predetermined impedance in the PCB between the signal and ground paths.

This novel combination of a PCB with a coplanar waveguide structure, offset through-holes and a BGA provides a good RF transition for microwaves through the PCB whilst maintaining reliable hermetic sealing.

### BRIEF DESCRIPTION OF THE DRAWINGS

In order that the invention may be better understood, a preferred embodiment will now be described, by way of example only, with reference to the accompanying drawings, in which:

FIG. 1 is a perspective view, partly broken away, of an hermetically sealed box embodying the invention, containing integrated circuits and having on its underside a BGA;

FIG. 2 is an exploded perspective view of two joined PCBs of the example shown in FIG. 1;

FIG. 3 shows four printed surface layers of the PCBs of FIGS. 1 and 2 illustrating the through-holes and the signal paths to the BGA;

FIG. 4 is a diagram showing a conventional coplanar waveguide;

FIG. 5 is a cross-section through a conventional IC assembly, corresponding to portion 61 of FIG. 6;

FIG. 6 is a partial perspective view of a radar antenna array having transmit/receive modules including hermetically sealed boxes 1 of the type shown in FIG. 1 and FIG. 5;

FIG. 7 is a diagram showing a sealed box on a test array;

FIG. 8 is a perspective view, partially broken away, of an hermetically sealed box 1a similar to box 1 of FIG. 1; and

FIG. 9 is a perspective exploded view of the components of the box 1a of FIG. 8, connected to a BGA.

### MORE DETAILED DESCRIPTION

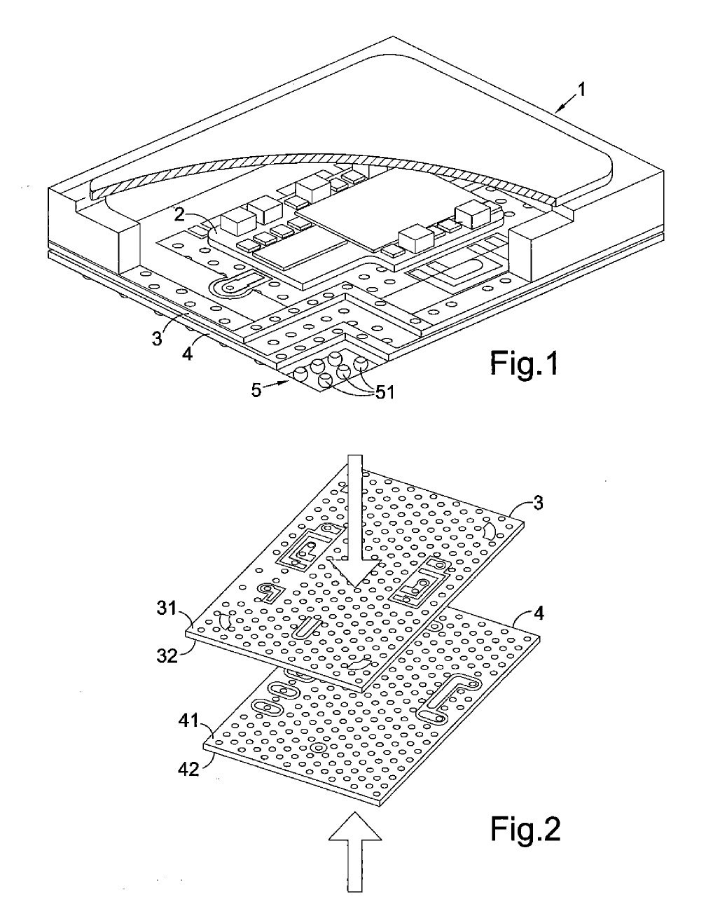

A micro BGA package for microwave RF comprising an hermetically sealed box 1 is shown in FIG. 1, and its underside is bonded to a BGA 5 comprising solder balls 51. The package has a multiplicity of integrated circuits on a substrate 2 bonded to the printed circuits of a PCB structure comprising two separate PCBs 3, 4 shown in greater detail in FIG. 2. The upper major surface 31 of PCB 3 is connected electrically and thermally to the various ICs above it. The underside layer 32 of PCB 3 is bonded to a corresponding upper layer 41 of the PCB 4, whose undersurface 42 is bonded to the BGA 5.

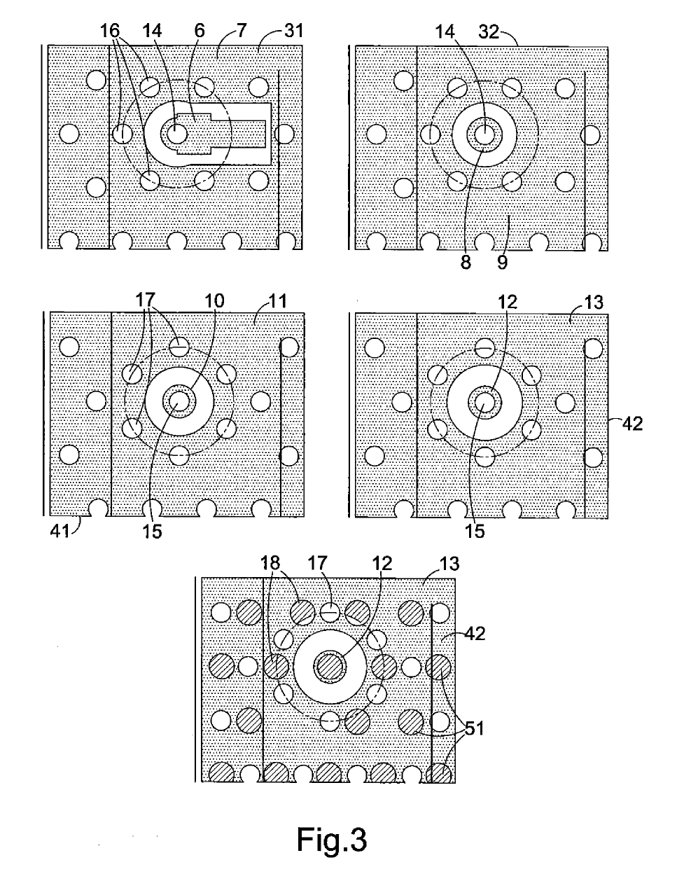

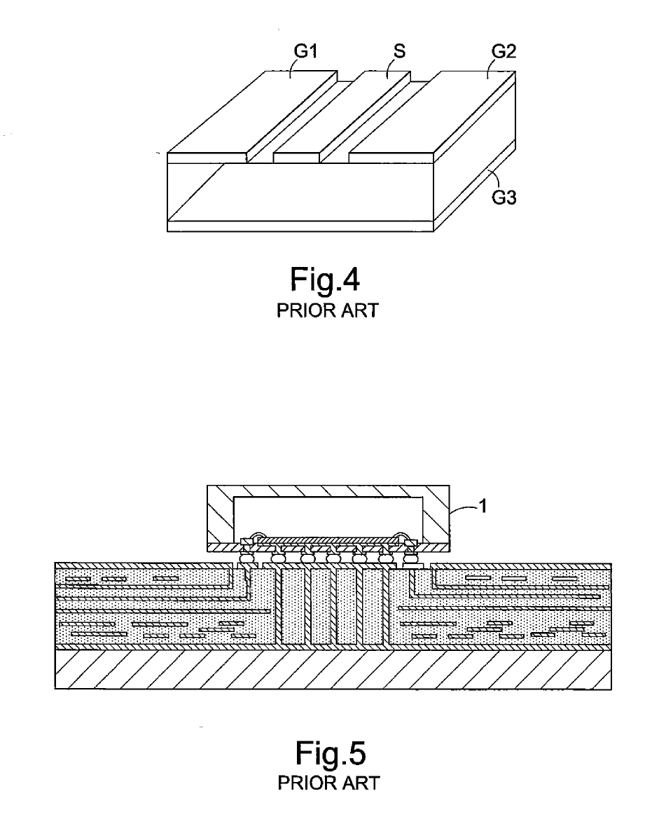

A microwave signal is transmitted across the upper major surface 31 in a signal path 6 shown in FIG. 3 which ends at a through-hole 14 extending through the top PCB 3 and in register with a corresponding through-hole 15 in the lower PCB 4, the through-hole 15 being surrounded by a ring shaped conductive pattern 10. This signal path structure is an example of a coplanar waveguide which in itself is well known and is illustrated in FIG. 4. The coplanar waveguide has a signal path S spaced on each side from ground paths G1, G2, and spaced by the thickness of the board from a further ground path G3.

A ground connection is made through metallic layer 7 on the upper surface 31, and corresponding metallic layers 9, 11 and 13 in the layers 32, 41 and 42 as shown in FIG. 3. The ground layers communicate using arrays of through-holes 16, 17 through the respective PCBs 3, 4. These electrically shield the signal path and the entire structure introduces a predetermined impedance, at the RF microwave frequencies which may for example be in the 4 to 20 GHz bandwidth. This impedance may be nominally 50 Ω, and is preferably in the range 10 to 100 Ω, more preferably 30 to 80 Ω.

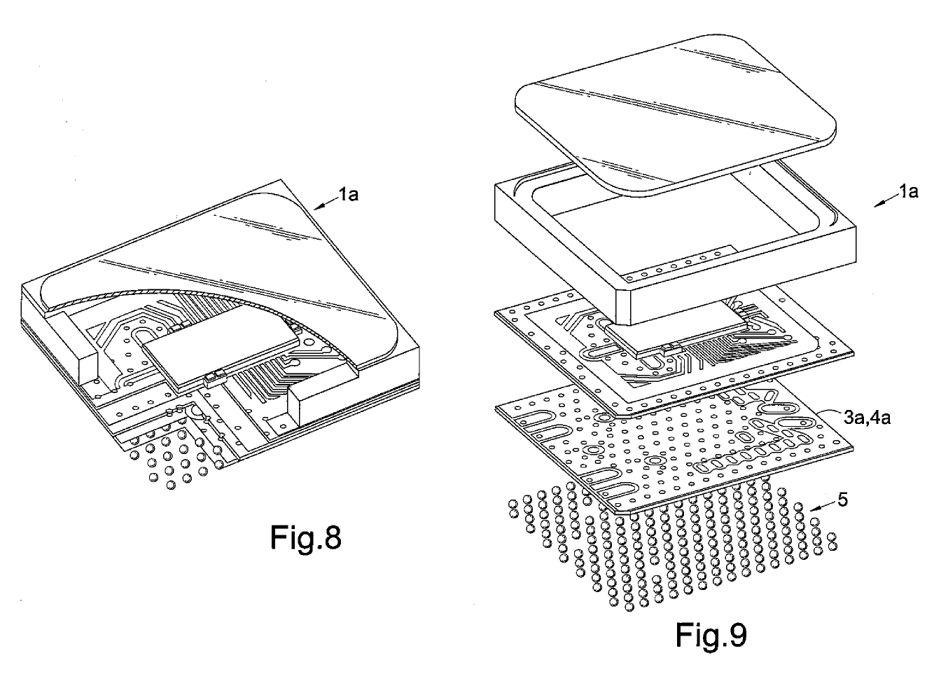

The BGA 5 forms a regular grid pattern, as shown in FIG. 3, and as illustrated in the further embodiment of FIGS. 8 and 9 described below. In this example, it is a diagonal grid with a pitch of about 0.8 mm and a 0.4 mm offset. The balls of the BGA are each 400 μm in diameter and in other examples are preferably in the range of 300 to 500 μm in diameter.

The set of through-holes 16 form a circular array around the signal path extending through the through-hole 14, 15, as shown in FIG. 3. There is a second set of through-holes 17 in the lower PCB 4, and the two circular arrays are opposed, with the same radius. However, the through-holes 16 are rotationally offset from the through-holes 17, so that they are in register with the midpoints of adjacent through-holes. In this example, the layer 31 has five through-holes 16, with a gap on the right hand side where a through-hole is redundant because it would cross the signal path of the coplanar waveguide. Four of these through-holes 16 are continued through the undersurface 32 of PCB 3. The upper major surface 41 of the lower PCB 4 has six equi-angularly disposed through-holes 17, precisely offset from the through-holes 16; these through-holes 17 also extend through the undersurface 42 to the plane of the BGA 5 as shown in FIG. 3. Since the balls of the BGA are in a diagonal rectangular grid, they cannot be selected to form precisely circular arrays of balls, but selected balls 18, shown in FIG. 3, can be in a nearly circular array to be bonded to the metal layer 13 quite close to the midpoints between adjacent through-holes 17 in the circular array.

Thus it will be appreciated that the signal path extends through the centres of the circular arrays of through-holes for the ground connection. The diameter of each ball of the BGA is less than the distance between adjacent through-holes of the PCB.

It will be appreciated that a good hermetic seal can be achieved between the two PCB layers, due to the offsets in the through-holes. The bonding between the PCBs, which may for example be RF organic substrates of Rogers RO 4003 material coated with gold or tin layers, preferably uses intra-metallic diffusion processes under high pressure. Intra-metallic diffusion soldering between the metal layers ensures very good thermal conductivity, as well as good hermetic sealing.

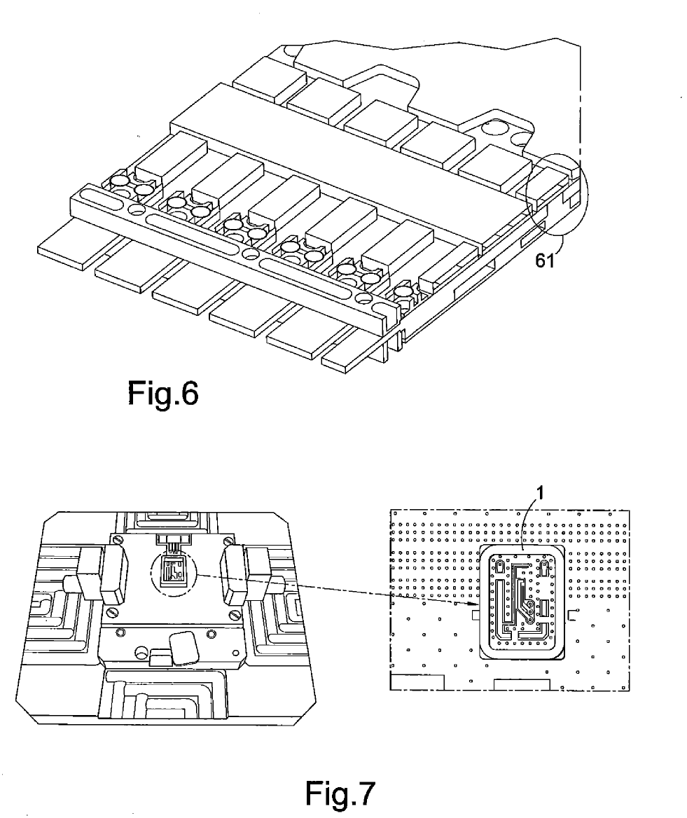

To illustrate the application of hermetically sealed packages embodying the invention, a radar antenna array structure is shown in FIG. 6, part 61 of which corresponds to the sectional view of FIG. 5. The transmit/receive module of this antenna circuit has several high power amplifiers in hermetically sealed boxes such as box 1 shown in FIG. 7. The overall structure provides good thermal heat dissipation from these amplifiers. A sealed box 1a embodying the invention and similar to box 1 of FIG. 1 is shown in FIGS. 8 and 9, which further illustrate the multi-layer PCB structure 3a, 4a adjoining a BGA 5.

1. An hermetically sealed microwave integrated circuit comprising:
a printed circuit board having at least a first layer and a second layer generally opposite the first layer, wherein the first and second layers each have an upper and a lower major surface, wherein the upper major surface of the first layer is electrically connected to an integrated circuit, and the lower major surface of the second layer is thermally and electrically connected to a ball grid array, the ball grid array comprising a plurality of balls;
a coplanar waveguide situated on the upper major surface of the first layer;
a microwave signal path that extends from a ball of the ball grid array through a signal-bearing through-hole in the first and second layers to the coplanar waveguide; and
a plurality of ground paths that extend from the balls of the ball grid array through a first plurality of ground through-holes in the first layer of the printed circuit board and through a second plurality of ground through-holes of the second layer of the printed circuit board, the first plurality of ground through-holes having an offset from the second plurality of ground through-holes,
wherein the offset produces a substantially hermetic seal across the printed circuit board while introducing a predetermined impedance in the printed circuit board between the microwave signal path and one or more of the plurality of ground paths.

2. A circuit according to claim 1, wherein the first plurality of ground through-holes are arranged in a first circular array and the second plurality of ground through-holes are arranged in a second circular array opposed to the first circular array, and the first plurality of ground through-holes are rotationally offset from the second plurality of ground through-holes.

3. A circuit according to claim 2, wherein the signal-bearing through-hole is substantially at a center of the first and second circular arrays.

4. A circuit according to claim 1, in which the integrated circuit is connected by another ball grid array to the lower major surface of the second layer.

5. A circuit according to claim 1, wherein a diameter of at least one ball of the ball grid array is less than a distance between adjacent through-holes of the printed circuit board.

6. A circuit according to claim 1, wherein the ground through-holes have diameters in a range of approximately 200 μm to approximately 400 μm.

7. A circuit according to claim 1, in which the balls of the ball grid array have diameters in a range of approximately 300 μm to approximately 500 μm.

8. A circuit according to claim 1, wherein the ball grid array is arranged in a diagonal grid.

9. A circuit according to claim 8, in which the ball grid array has a pitch of approximately 0.8 mm and an offset of approximately 0.4 mm.

10. A circuit according to claim 1, wherein an impedance between the microwave signal path and a ground in the PCB is in a range of approximately 30 ohms to approximately 80 ohms.

11. A circuit according to claim 9, wherein the impedance is approximately 50 ohms.
